(19) United States
(12) Patent Application Publication
(10) Pub. No.: US 2006/0166442 A1
(43) Pub. Date: Jul. 27, 2006

(54) Method for manufacturing semiconductor device

(75) Inventors: Hae-Wang Lee, Suwon-Si (KR); Key-Min Lee, Seocho-gu (KR); Tae-Soo Park, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/338,269

(22) Filed: Jan. 24, 2006

(30) Foreign Application Priority Data
Jan. 25, 2005 (KR) 2005-06835

(51) Int. Cl. H01L 21/336

(52) U.S. Cl. 438/259

(57) ABSTRACT

In a method for manufacturing a semiconductor device, a mask layer is formed on a semiconductor substrate. The mask layer and the substrate are patterned to form a device isolation layer defining an active region. The mask layer and the substrate are patterned in the active region to form a trench. A gate oxide layer is formed on the substrate at inner surfaces of the trench. The trench including the gate oxide layer is filled with a conductive layer for forming a gate electrode. The mask layer is then removed. Misalignment between the gate electrode and the substrate is thereby prevented. The gate electrode is made of polysilicon. By performing an ion implanting process, a conductivity type of the gate electrode is determined to provide a semiconductor device of a desired conductivity type.

### PRIORITY STATEMENT

This application claims priority to Korean Patent Application No. 2005-06835, filed on Jan. 25, 2005 in the Korean Intellectual Property Office, the disclosure of which is incorporated herein in its entirety by reference.

### BACKGROUND OF THE INVENTION

1. Field of the Invention

The present invention relates to a method for manufacturing a semiconductor device and, more particularly, to a method for manufacturing a semiconductor device having a recessed channel.

2. Description of Related Art

With the continuing trend toward more highly integrated semiconductor devices, the widths of MOS transistors are continuously reduced. Such reduction results in generation of a short channel effect which, in turn, causes a threshold voltage of a transistor to be reduced. In addition, the switching characteristics of a transistor are degraded by generation of a leakage current, and punchthrough is more likely to occur. Punchthrough is a serious problem, and occurs when a depletion region of a drain junction merges with a depletion region of a source junction. If punchthrough occurs, a breakdown voltage characteristic of the transistor between a source region and a drain region is degraded.

A gate electrode structure having a recessed channel has been suggested in order to suppress the short channel effect. Such a recessed channel results in an increased channel length. This type of gate electrode structure is disclosed in U.S. Patent Application Publication No. 2004/0126948. According to the '948 publication, a recessed gate electrode structure is formed to overcome a short channel effect.

FIG. 1A through FIG. 1D are cross-sectional views that describe a transistor manufacturing method in accordance with the disclosure of the '948 publication.

Referring to FIG. 1A, pad oxide 11 and pad nitride 13 layers are formed on a semiconductor substrate 10. Device isolation layers 15 are then formed to define active regions on the substrate 10. As illustrated in FIG. 1B, the pad nitride 13 and pad oxide 11 layers formed on an active region of the substrate 10, and the substrate 10 itself, are successively patterned to form a gate trench 16.

The patterned pad nitride 13 and pad oxide 11 layers are subsequently removed. Next, a gate oxide 17 is formed, and a polysilicon layer 19 is deposited. As illustrated in FIG. 1C, the polysilicon layer 19 is polished until a top surface of the device isolation layer 15 is exposed. A metal barrier layer 21, a tungsten layer 23, and a nitride layer 25 are then stacked. As illustrated in FIG. 1D, a gate electrode 30 is formed by means of a patterning process.

In such a process, after removal of the pad nitride, the polysilicon layer for a gate is deposited and patterned to form a gate electrode. Misalignment can therefore occur between gate portion A of FIG. 1D, i.e., the top of the gate conductive layer 19, and the substrate 10. Particularly, if misalignment of the gate electrode 30 occurs, the threshold voltage of the resulting device can vary. As a result, reliable and precise device characteristics are not achieved.

Conventionally, a transistor using polysilicon doped with N-type impurities is typically formed for application as a peripheral circuit. Meanwhile, dual-gate type complementary metal oxide semiconductor (CMOS) devices have become popular. Such dual-gate type CMOS devices offer various advantageous properties. To form a P-channel metal oxide semiconductor field effect transistor (PMOSFET) after a gate electrode is formed using typical polysilicon doped with N-type impurities, P-type impurities of higher concentration must be implanted for converting the N-type gate electrode into a P-type gate electrode. During the above process, problems such as fluctuation of a threshold voltage are caused by boron penetration. Thus, it is difficult to stably maintain device characteristics.

### SUMMARY OF THE INVENTION

Exemplary embodiments of the present invention are directed to a method for manufacturing a semiconductor device in a manner that avoids misalignment of a gate electrode.

In a first aspect, the present invention is directed to a method for manufacturing a semiconductor device. A mask layer is formed on a semiconductor substrate. The mask layer and the substrate are patterned to form a device isolation layer defining an active region. The mask layer and the substrate are patterned in the active region to form a trench. A gate oxide layer is formed on the substrate at inner surfaces of the trench. The trench including the gate oxide layer is filled with a conductive layer for forming a gate electrode. The mask layer is then removed.

In one embodiment, filling the trench with the conductive layer comprises: providing a polysilicon layer in the trench and on the mask layer and removing the polysilicon layer until the mask layer is exposed; reducing a height of the polysilicon layer filled in the trench; and depositing a silicide layer to re-fill the trench.

In another aspect, the present invention is directed to a method for manufacturing a semiconductor device. A mask layer is formed on a substrate including a cell region and a peripheral circuit region. The mask layer and the substrate are patterned to form a device isolation layer defining an active region. The mask layer and the substrate are patterned in the active region of the cell region to form a trench. A gate oxide layer is formed on the substrate at inner surfaces of the trench. The trench including the gate oxide layer is filled with an undoped conductive layer to form a gate electrode. The mask layer is removed. A gate electrode is formed at the peripheral region while masking the cell region, the gate electrode comprising an undoped conductive layer. An ion implanting process is performed to determine a conductivity type of the gate electrode and to form an impurity region on the substrate.

In one embodiment, the undoped conductive layer comprises undoped polysilicon.

In another embodiment, performing an ion implanting process comprises: performing a first ion implanting process for the cell region and the peripheral circuit region; and after forming a spacer on a sidewall of the gate electrode, performing a second ion implanting process for the peripheral circuit region while masking the cell region.

In another embodiment, a concentration and an energy of impurities in the second ion implanting process are higher than those of impurities in the first ion implanting process.

Since the gate electrode is formed not by means of a patterning process, misalignment between the substrate and the gate electrode does not occur.

In addition, a stable threshold voltage is achieved by forming the gate electrode with undoped polysilicon and then performing ion implantation to achieve a desired conductivity type.

### BRIEF DESCRIPTION OF THE DRAWINGS

The foregoing and other objects, features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1A through FIG. 1D are cross-sectional views for explaining a conventional method for manufacturing a semiconductor device.

FIG. 2A through FIG. 2D are cross-sectional views for explaining a method for manufacturing a semiconductor device according to an embodiment of the present invention.

FIG. 3A through FIG. 3F are cross-sectional views for explaining a method for manufacturing a semiconductor device according to another embodiment of the present invention.

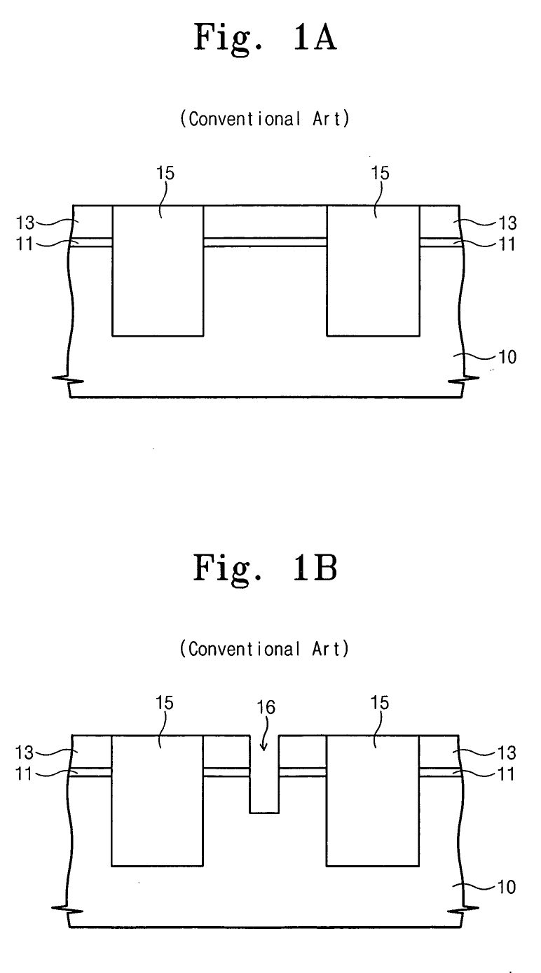

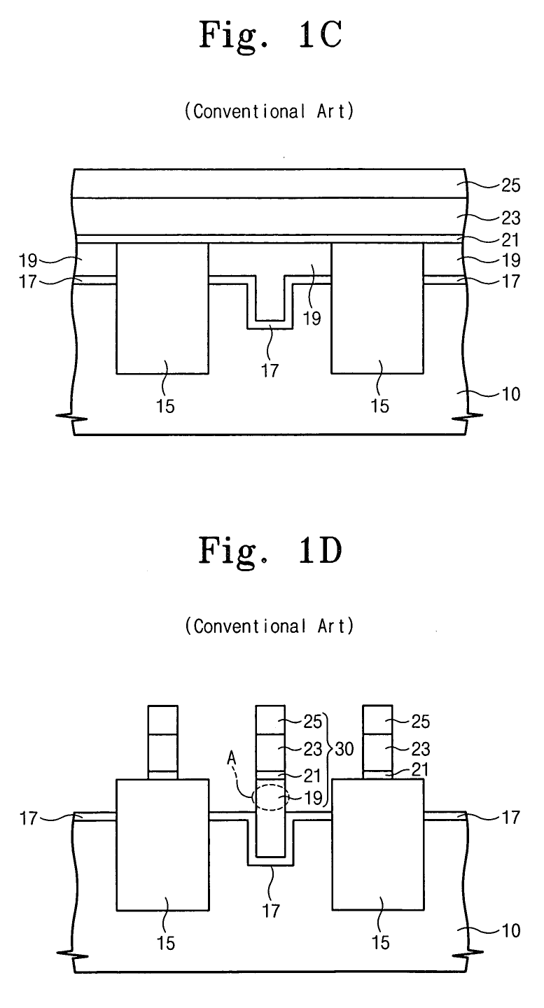

### DETAILED DESCRIPTION OF THE INVENTION

The present invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete. In the drawings, the height of layers and regions are exaggerated for clarity. It will also be understood that when a layer is referred to as being “on” another layer or substrate, it can be directly on the other layer or substrate, or intervening layers may also be present. Like numbers refer to like elements throughout.

### Embodiment 1

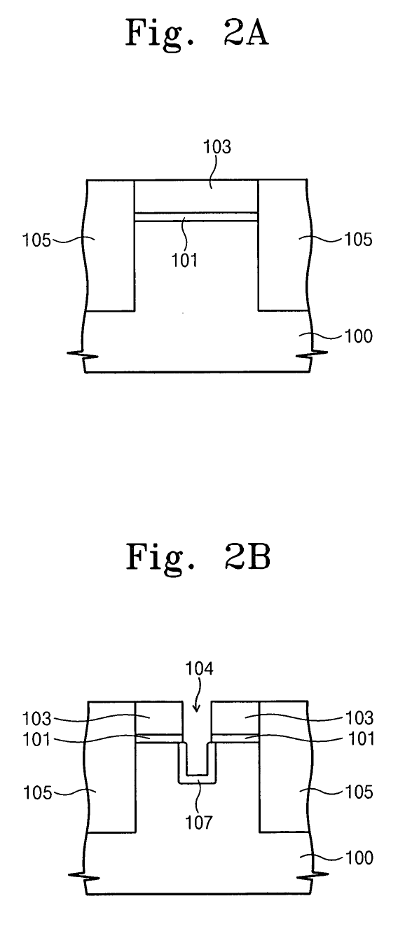

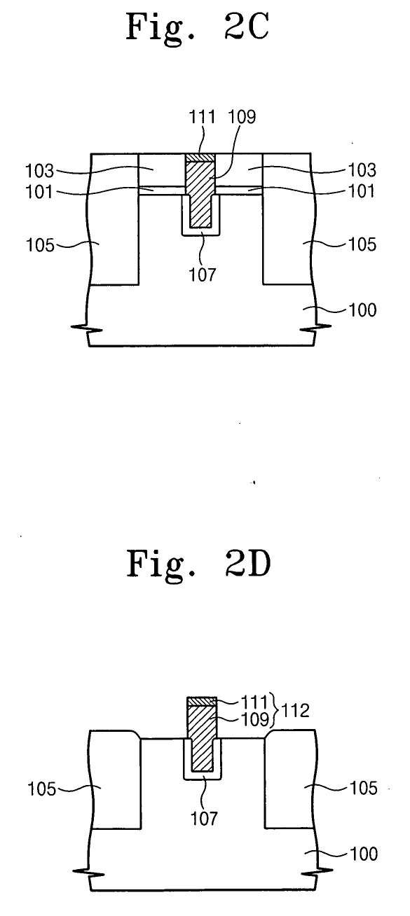

The first embodiment of the present invention will be described with reference to FIG. 2A through FIG. 2D.

Referring to FIG. 2A, pad oxide 101 and pad nitride 102 layers are formed on a semiconductor substrate 100. The formation of the pad oxide 101 is provided using dry or wet oxidation at a predetermined temperature to cure crystalline defects on the substrate 100 or to treat a surface of the substrate 100. Typically, the pad nitride 103 comprises silicon nitride (SiN).

The pad nitride 103, the pad oxide 101, and the substrate 100 are successively etched to form a trench and to define an active region. High density plasma oxide (HDP oxide) for a trench insulation layer is deposited to fill the trench. A chemical mechanical polishing (CMP) process is carried out to form a device isolation layer 105 having a predetermined height.

Referring to FIG. 2B, the pad nitride 103, the pad oxide 101, and the substrate 100 formed on the active region defined by the device isolation layer 105 are successively patterned to form a gate trench 104. In consideration of the desired channel length, the gate trench 104 is formed to have a predetermined width and depth. A gate oxide layer 107 is formed on inner surfaces of the portion of the trench 104 that is formed in the substrate 100 by means of an annealing process.

Referring to FIG. 2C, a first conductive layer is deposited. A chemical mechanical polishing (CMP) process is performed using the pad nitride 103 as an etch barrier layer. A first conductive layer 109 filling the trench 104 is selectively etched to reduce its height. Preferably, the first conductive layer 109 comprises polysilicon.

After a second conductive layer 111 is deposited, a CMP or etch-back process is performed using the pad nitride 103 as an etch barrier layer. The second conductive layer 111 comprises silicide such as, for example, tungsten silicide (WSiₓ). Although FIG. 2 demonstrates that first and second conductive, layers are stacked sequentially, in another embodiment, a single conductive layer may be provided.

Referring to FIG. 2D, the pad nitride 103 and the pad oxide 101 are removed. When the pad oxide 101 is removed, an upper portion of the device isolation layer 105 is partially etched, which reduces the height of the device isolation layer 105 and sidewalls of a top portion of the gate electrode 112 are exposed.

In the above embodiment, the pad oxide and pad nitride layers, i.e. a mask layer, is formed, a gate trench is formed though the mask layer and into the substrate and a gate electrode is formed in the trench in a manner that prevents misalignment between the gate electrode and the substrate.

### Embodiment 2

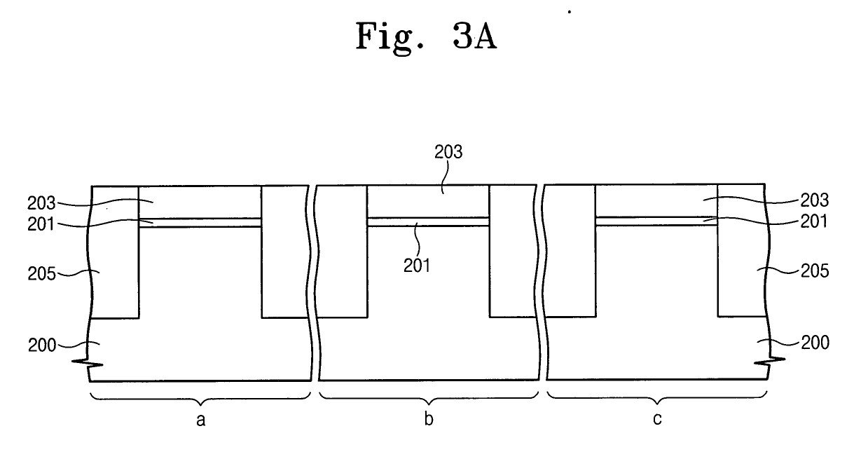

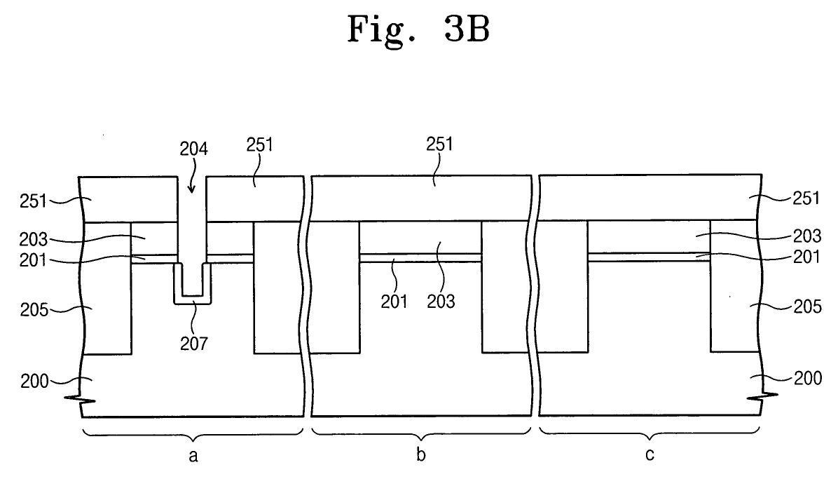

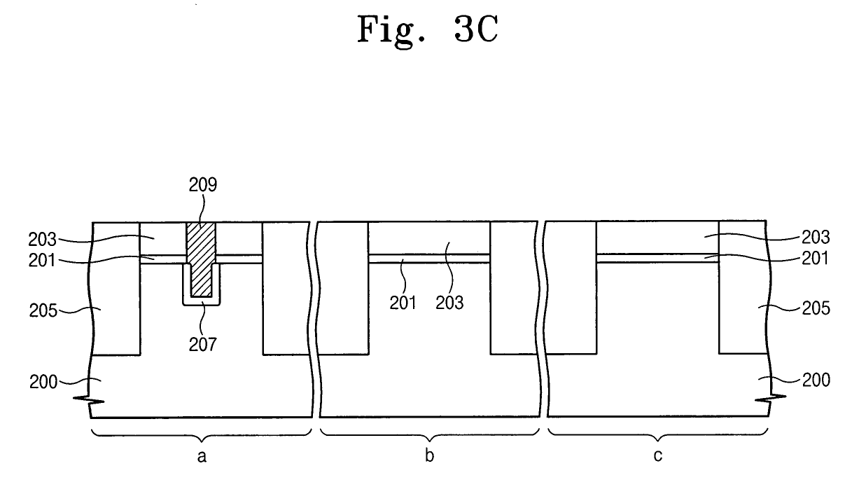

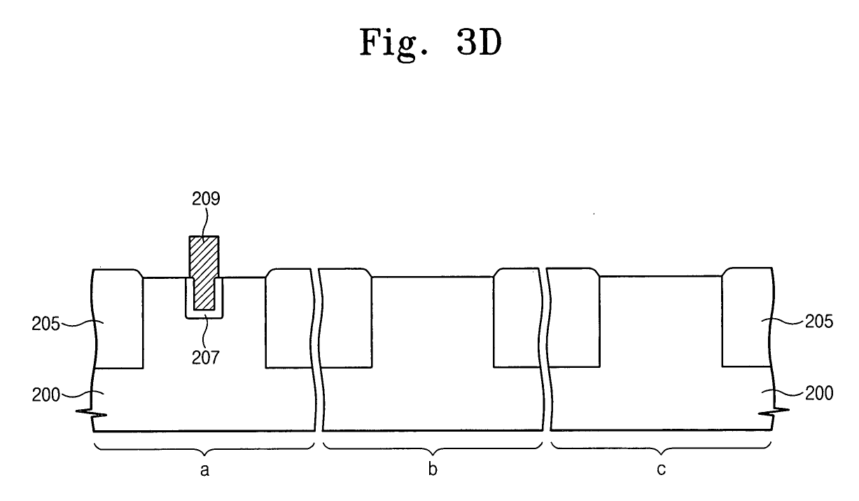

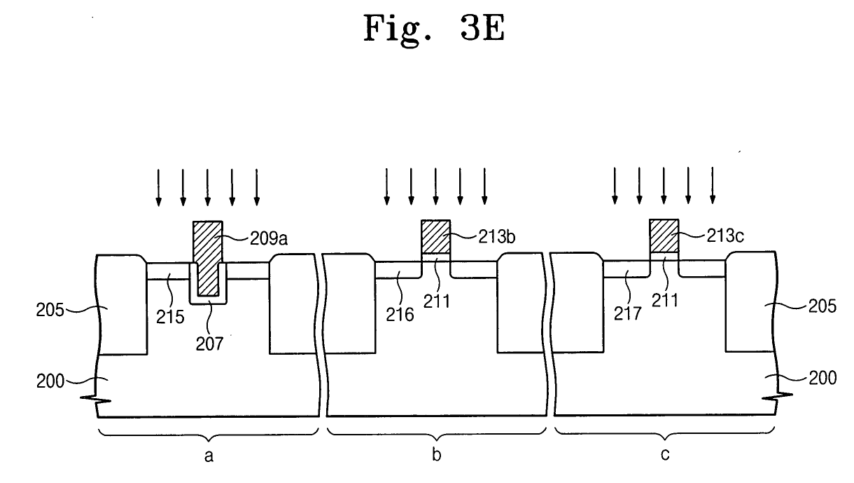

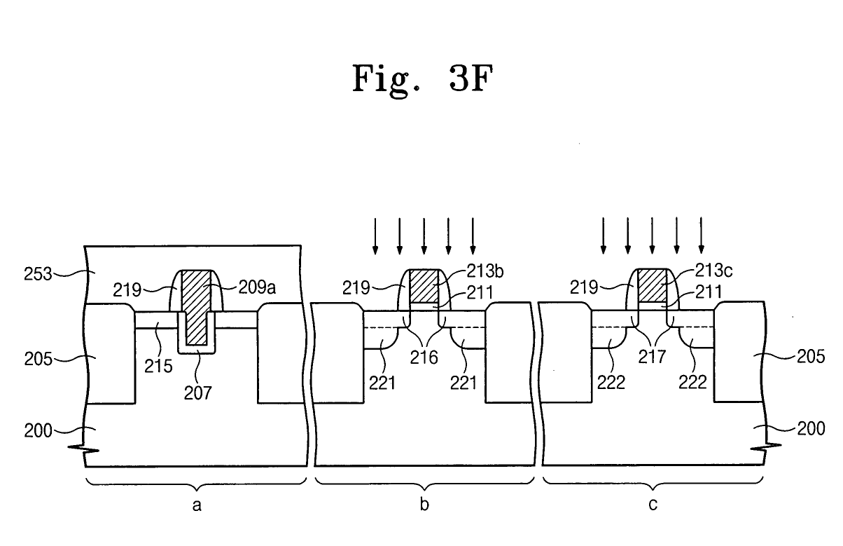

The second embodiment of the present invention is now described with reference to FIG. 3A through FIG. 3F, in which reference numerals “a”, “b”, and “c” denote a cell region, a peripheral circuit region where an NMOS transistor is formed (hereinafter referred to “NMOS region”), and a peripheral circuit region where a PMOS transistor is formed (hereinafter referred to as “PMOS region”). The configuration of portions indicated by reference numerals a, b, and c is not limited to the respective regions illustrated and may be disposed at parts of different regions.

Referring to FIG. 3A, pad oxide 201 and pad nitride 203 are formed on a semiconductor substrate 100 including a cell region “a”, an NMOS region “b”, and a PMOS region “c”. The pad oxide 201 and the pad nitride 203 are formed in the same manner as that described above in connection with the first embodiment. The pad nitride 203, the pad oxide 201, and the substrate 200 are successively patterned to form an isolation trench. After HDP oxide is deposited in the isolation trench, a device isolation layer 205 is formed using CMP to define active regions between the trenches.

Referring to FIG. 3B, a photoresist pattern 251 is formed on the resulting structure. A gate trench 204 is formed in the cell region “a”. Specifically, the gate trench 204 is formed on the active region defined by the device isolation layer 205 and has a predetermined width and height in consideration of the desired channel length. A gate insulation layer 207 is formed in the substrate 200 in a lower portion of the gate trench 204 by means of an annealing process. Any photoresist pattern 251 remaining on the NMOS region “b”, the PMOS region “c”, and the cell region “a” is removed using a cleaning process.

Referring to FIG. 3C, a conductive layer is deposited. A CMP process using the pad nitride 203 as an etch barrier layer is performed to form a first conductive pattern 209 that fills the gate trench 204. Thus, the first conductive pattern 209 is formed to constitute a gate electrode in the cell region “a”. Although the conductive layer can generally comprise polysilicon, a conductive layer of this invention is preferably formed of undoped polysilicon in order to provide a conductivity type for a gate electrode by means of a subsequent ion implanting process.

Referring to FIG. 3D, the pad nitride 203 and the pad oxide 201 layers are removed to expose a top surface of the first conductive pattern 209 in the cell region “a” which extends above the substrate 200. Since the device isolation layer 205 is partially removed during removal of the pad oxide 201, the height of the device isolation layer 205 is reduced. Although not shown in the figure, after the cell region “a” is covered with a photoresist pattern, second conductive patterns (213b and 213c of FIG. 3E) are formed to constitute gate oxide (211 of FIG. 3E) and a gate electrode in the NMOS region “b” and the PMOS region “c” of the device. Also, the second conductive patterns are preferably made of undoped polysilicon such that a conductivity type of a gate electrode can be decided by means of a subsequent ion implanting process.

Referring to FIG. 3E, first impurity regions 215, 216, and 217 are formed at the cell region “a”, the NMOS region “b”, and the PMOS region “c” by means of an ion implanting process. As described above, impurities are selectively (P-type or N-type impurities) implanted based on desired characteristics of the respective transistors to determine the resulting conductivity type of the gate electrode in this manner, stable devices are readily formed. Although contemporaneous ion implantation for all regions is illustrated in the figure, ion implantation for one of the regions “b” and “c” may be performed based on a conductivity type of a transistor to be formed on the cell region “a” simultaneously with the ion implantation for the cell region “a”. For example, if a transistor to be formed on the cell region “a” is an NMOS transistor, ion implantations for the cell region “a” and the NMOS region “b” are performed simultaneously while the PMOS region “c” is covered with a mask layer. Even in the case where an NMOS transistor is formed in the cell region “a”, different ion implantation procedures can be independently performed for the cell region “a” and the NMOS region “b” if impurity implanting concentrations are to change based on the desired characteristics of the resulting devices.

Since the first conductive pattern 209 shown in FIG. 3D is originally formed of undoped polysilicon and since the first conductive pattern 209a shown in FIG. 3E includes doped polysilicon, they are denoted by different reference numerals.

Referring to FIG. 3F, silicon nitride is deposited and etched back to form a spacer 219 on sidewalls of the first conductive pattern 209a and second conductive patterns 213b and 213c which protrude from the substrate 200. A photoresist pattern 253 is formed on the cell region “a” to protect the cell region “a”. Additional ion implantation is performed for the NMOS region “b” and the PMOS region “a” to form second impurity regions 221 and 222. In the additional ion implantation, impurities of the same type as the implanted impurities of FIG. 3E are additionally implanted. Since the additional ion implantation is performed with a higher concentration and at a higher energy level than the above-mentioned ion implantation, the second impurity regions 221 and 222 have greater depth than the first impurity regions 215, 216, and 217. Although ion implantations for the NMOS region “b” and the PMOS region “c” are illustrated as being performed simultaneously, they are sequentially performed for the respective regions because conductivity types of impurities to be implanted to the NMOS region “b” and the PMOS region “c” are different from each other. The first impurity regions 215, 216, and 217 and the second impurity regions are formed as source and drain regions by means of subsequent processes, respectively.

Although not shown in the figure, a silicide forming process is performed. Cobalt (Co) and titanium (Ti) are stacked on the resultant structure, and silicide is then formed on first and second patterns 209a, 213b, and 213c by means of an annealing process and any remaining cobalt and/or titanium is removed. Thereafter, fabrication of the semiconductor device is completed by means in a conventional manner.

According to the present invention, when a gate electrode is formed, it is not necessary to pattern the gate electrode. Since misalignment between a substrate and the gate electrode does not occur, characteristics of semiconductor devices do not vary. In addition, the gate electrode is originally formed with undoped polysilicon, and impurities of desired conductivity type are implanted in a subsequent ion implanting process. Thus, semiconductor devices having desired stable characteristics are readily manufactured.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A method for manufacturing a semiconductor device, comprising:
forming a mask layer on a semiconductor substrate;
patterning the mask layer and the substrate to form a device isolation layer defining an active region;
patterning the mask layer and the substrate in the active region to form a trench;
forming a gate oxide layer on the substrate at inner surfaces of the trench;
filling the trench including the gate oxide layer with a conductive layer for forming a gate electrode; and
removing the mask layer.

2. The method of claim 1, wherein filling the trench with the conductive layer comprises:
providing a polysilicon layer in the trench and on the mask layer and removing the polysilicon layer until the mask layer is exposed;
reducing a height of the polysilicon layer filled in the trench; and
depositing a silicide layer to re-fill the trench.

3. A method for manufacturing a semiconductor device, comprising:
forming a mask layer on a substrate including a cell region and a peripheral circuit region;
patterning the mask layer and the substrate to form a device isolation layer defining an active region;
patterning the mask layer and the substrate in the active region of the cell region to form a trench;
forming a gate oxide layer on the substrate at inner surfaces of the trench;
filling the trench including the gate oxide layer with an undoped conductive layer to form a gate electrode;
removing the mask layer;
forming a gate electrode at the peripheral region while masking the cell region, the gate electrode comprising an undoped conductive layer; and
performing an ion implanting process to determine a conductivity type of the gate electrode and to form an impurity region on the substrate.

4. The method of claim 3, wherein the undoped conductive layer comprises undoped polysilicon.

5. The method of claim 3, wherein performing an ion implanting process comprises:
performing a first ion implanting process for the cell region and the peripheral circuit region; and
after forming a spacer on a sidewall of the gate electrode, performing a second ion implanting process for the peripheral circuit region while masking the cell region.

6. The method of claim 5, wherein a concentration and an energy of impurities in the second ion implanting process are higher than those of impurities in the first ion implanting process.
